(19) United States
(12) Patent Application Publication
(10) Pub. No.: US 2025/0223692 A1
(43) Pub. Date: Jul. 10, 2025

(54) SUBSTRATE PROCESSING METHOD, METHOD OF MANUFACTURING SEMICONDUCTOR DEVICE, RECORDING MEDIUM AND SUBSTRATE PROCESSING APPARATUS

(71) Applicant: KOKUSAI ELECTRIC CORPORATION, Tokyo (JP)

(72) Inventor: Arito OGAWA, Toyama-shi (JP)

(73) Assignee: KOKUSAI ELECTRIC CORPORATION, Tokyo (JP)

(21) Appl. No.: 19/090,086

(22) Filed: Mar. 25, 2025

Related U.S. Application Data
(63) Continuation of application No. PCT/JP2022/035999, filed on Sep. 27, 2022.

(51) Int. Cl. C23C 16/44; C23C 16/455; C23C 16/52; H01L 21/3205

(52) U.S. Cl. CPC C23C 16/4408; C23C 16/4412; C23C 16/45544; C23C 16/52; H01L 21/32051

(57) ABSTRACT

A technique comprises: (a) supplying a first processing gas into the processing container when exhausting of the atmosphere in the processing container is stopped; (b) exhausting the atmosphere in the processing container to the first exhaust pipe and the storage of the second exhaust pipe when the exhaust valve is closed and the air supply valve is opened, after (a); (c) exhausting the atmosphere in the processing container by the first exhaust pipe when the air supply valve is closed to stop the exhaust of the atmosphere in the processing container by the storage, after (b); (d) supplying a second processing gas into the processing container when the air supply valve is closed to stop the exhaust of the atmosphere in the processing container by the storage, after (c); and (e) performing (a) to (d) to process the substrate in the processing container.

### CROSS-REFERENCE TO RELATED APPLICATION

This application is a Bypass Continuation Application of PCT International Application No. PCT/JP2022/035999, filed on Sep. 27, 2022, the entire contents of which are incorporated herein by reference.

### BACKGROUND

### Field

The present disclosure relates to a substrate processing method, a method of manufacturing a semiconductor device, a recording medium and a substrate processing apparatus.

### Description of the Related Art

For example, a tungsten (W) film may be used as a word line of a NAND flash memory or a DRAM having a three-dimensional structure. In some cases, for example, a titanium nitride (TiN) film is used as a barrier film between the W film and an insulating film. In addition, a film having a lower resistance than the W film is desired. For example, a molybdenum (Mo) film may be used.

### SUMMARY

In formation of a low-resistance film, in a case where film formation is performed using a reactant gas having poor reactivity as a first processing gas, an amount of supply of the reactant gas into a processing container may be increased. On the other hand, in a case where the amount of supply of the reactant gas is increased, a discharge time is large when the reactant gas is discharged from the processing container to a detoxifier through a pump.

The present disclosure provides a technique for shortening a discharge time of a gas from an exhaust system and improving processing throughput.

### BRIEF DESCRIPTION OF THE DRAWINGS

FIG. 1 is a longitudinal sectional view schematically illustrating a vertical processing furnace of a substrate processing apparatus according to an embodiment of the present disclosure.

FIG. 2 is a schematic transverse sectional view taken along a line A-A in FIG. 1.

FIG. 3 is a schematic configuration diagram of a controller of the substrate processing apparatus according to the embodiment of the present disclosure, and is a diagram illustrating a control system of the controller as a block diagram.

FIG. 4 is a diagram illustrating substrate processing steps according to the embodiment of the present disclosure.

FIG. 5A is a diagram illustrating one of the substrate processing steps according to the embodiment of the present disclosure. FIG. 5B is a diagram illustrating one of the substrate processing steps according to the embodiment of the present disclosure. FIG. 5C is a diagram illustrating one of the substrate processing steps according to the embodiment of the present disclosure. FIG. 5D is a diagram illustrating one of the substrate processing steps according to the embodiment of the present disclosure. FIG. 5E is a diagram illustrating one of the substrate processing steps according to the embodiment of the present disclosure. FIG. 5F is a diagram illustrating one of the substrate processing steps according to the embodiment of the present disclosure.

### DETAILED DESCRIPTION

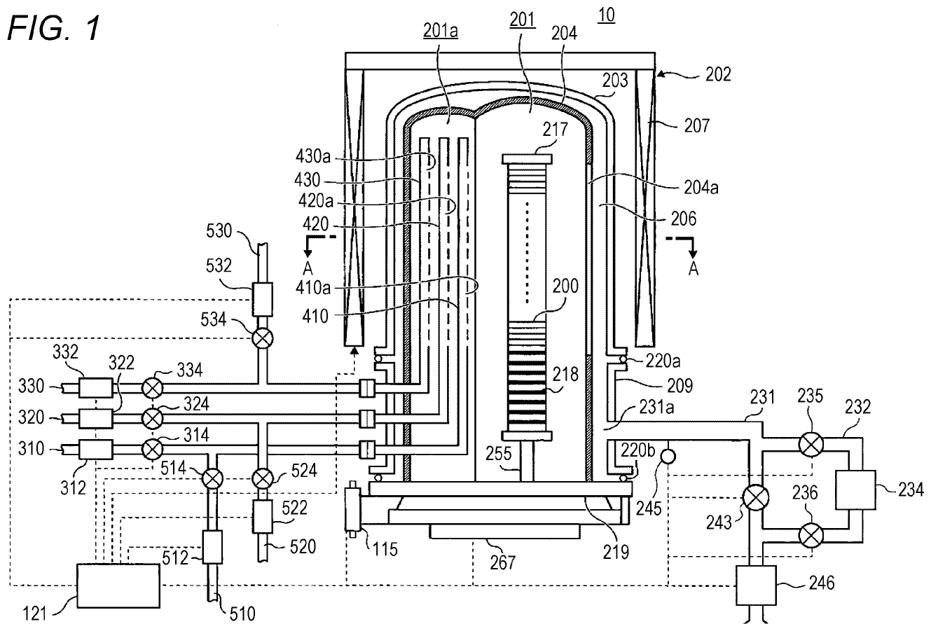

Hereinafter, description will be given with reference to FIGS. 1 to 4. The drawings used in the following description are all schematic, and dimensional relationships between elements, ratios between elements, and the like illustrated in the drawings do not necessarily coincide with actual ones. Between a plurality of drawings, the dimensional relationship between the respective elements and the ratio between the respective elements do not necessarily coincide with each other.

### (1) Configuration of Substrate Processing Apparatus

A substrate processing apparatus 10 includes a processing furnace 202 provided with a heater 207 serving as a heating means (heating mechanism or heating system). The heater 207 has a cylindrical shape and is vertically installed by being supported by a heater base (not illustrated) serving as a holding plate. In addition, the substrate processing apparatus 10 includes an outer tube 203 as an example of a processing container, a first exhaust pipe 231, a second exhaust pipe 232, a storage 234, an air supply valve 235, an exhaust valve 236, gas supply pipes 310, 320, 330, 510, 520, and 530 as examples of a gas supplier, and a controller 121 as an example of a controller.

Inside the heater 207, the outer tube 203 constituting a reaction tube (a reaction container, a processing container) is disposed concentrically with the heater 207. The outer tube 203 includes, for example, a heat-resistant material such as quartz (SiO₂) or silicon carbide (SiC) and is formed in a cylindrical shape in which the upper end is closed and the lower end is open. Below the outer tube 203, a manifold (inlet flange) 209 is disposed concentrically with the outer tube 203. The manifold 209 includes, for example, a metal such as stainless steel (SUS) and is formed in a cylindrical shape in which the upper end and the lower end are open. Between the upper end portion of the manifold 209 and the outer tube 203, an O-ring 220a serving as a seal member is provided. The manifold 209 is supported by the heater base, whereby the outer tube 203 is vertically installed.

Inside the outer tube 203, an inner tube 204 constituting the reaction container is disposed. The inner tube 204 includes, for example, a heat-resistant material such as quartz or SiC, and is formed in a cylindrical shape in which the upper end is closed and the lower end is open. Mainly the outer tube 203, the inner tube 204, and the manifold 209 constitute the processing container (reaction container). In a cylindrical hollow portion of the processing container (inside the inner tube 204), a process chamber 201 is formed.

The process chamber 201 can accommodate wafers 200 serving as substrates in a state where the wafers 200 are arranged in multiple stages in the vertical direction in a horizontal posture by a boat 217 serving as a support. In the process chamber 201 (processing container), processing of the wafers 200 is performed.

In the process chamber 201, nozzles 410, 420, and 430 are provided so as to penetrate the side wall of the manifold 209 and the inner tube 204. The nozzles 410, 420, and 430 are connected to gas supply pipes 310, 320, and 330, respectively. Note that the processing furnace 202 of the present embodiment is not limited to the above-described form.

In the gas supply pipes 310, 320, and 330, mass flow controllers (MFCs) 312, 322, and 332 are respectively provided that are flow rate control devices (flow rate controllers). In addition, the gas supply pipes 310, 320, and 330 are respectively provided with valves 314, 324, and 334 that are on-off valves. The valves 314, 324, and 334 of the gas supply pipes 310, 320, and 330 are respectively connected, on the downstream sides thereof, to gas supply pipes 510, 520, and 530 that supply an inert gas. The gas supply pipes 510, 520, and 530 are respectively provided with MFCs 512, 522, and 532 that are flow rate control devices (flow rate controllers), and valves 514, 524, and 534 that are on-off valves, in this order from the upstream side. These gas supply pipes are examples of a gas supplier capable of supplying a first processing gas (for example, reducing gas) and a second processing gas (for example, source gas) to the process chamber 201 (processing container).

The nozzles 410, 420, and 430 are coupled to tip portions of the gas supply pipes 310, 320, and 330, respectively. The nozzles 410, 420, and 430 are formed as L-shaped nozzles, and horizontal portions thereof are provided so as to penetrate the side wall of the manifold 209 and the inner tube 204. Vertical portions of the nozzles 410, 420, and 430 are provided inside a preliminary chamber 201a, and in the preliminary chamber 201a, provided so as to extend to the upper side (the upper side in the arrangement direction of the wafers 200) along the inner wall of the inner tube 204. The preliminary chamber 201a has a channel shape (groove shape) that is formed so as to protrude outwardly in a radial direction of the inner tube 204 and to extend in the vertical direction.

The nozzles 410, 420, and 430 are provided so as to extend from a lower region of the process chamber 201 to an upper region of the process chamber 201, and respectively provided with a plurality of gas supply holes 410a, 420a, and 430a at positions facing the wafers 200. As a result, a processing gas is supplied from each of the gas supply holes 410a, 420a, and 430a of the nozzles 410, 420, and 430 to the wafers 200. A plurality of the gas supply holes 410a, 420a, and 430a are provided from a lower portion to an upper portion of the inner tube 204, have the same opening area, and are provided at the same opening pitch. Note that the gas supply holes 410a, 420a, and 430a are not limited to the above-described form.

For example, the opening area may be gradually increased from the lower portion to the upper portion of the inner tube 204. As a result, it is possible to make a flow rate of the gas supplied from the gas supply holes 410a, 420a, and 430a more uniform.

The plurality of gas supply holes 410a, 420a, and 430a of the nozzles 410, 420, and 430 are provided at height positions from the lower portion to the upper portion of the boat 217 described later.

Thus, the processing gas supplied from the gas supply holes 410a, 420a, and 430a of the nozzles 410, 420, and 430 into the process chamber 201 is supplied to the entire regions of the wafers 200 accommodated from the lower portion to the upper portion of the boat 217. It is sufficient that the nozzles 410, 420, and 430 are provided so as to extend from the lower region to the upper region of the process chamber 201, but the nozzles are preferably provided so as to extend to the vicinity of a ceiling of the boat 217.

From the gas supply pipe 310, a source gas containing a metal element (metal-containing gas) is supplied as the processing gas into the process chamber 201 through the MFC 312, the valve 314, and the nozzle 410.

From the gas supply pipe 320, a reducing gas is supplied as the processing gas into the process chamber 201 through the MFC 322, the valve 324, and the nozzle 420.

From the gas supply pipe 330, a gas containing a group 15 element different from the reducing gas is supplied as the processing gas into the process chamber 201 via the MFC 332, the valve 334, and the nozzle 430.

From the gas supply pipes 510, 520, and 530, for example, an argon (Ar) gas is supplied as the inert gas into the process chamber 201 through the MFCs 512, 522, and 532, the valves 514, 524, and 534, and the nozzles 410, 420, and 430, respectively. Hereinafter, an example will be described of using Ar gas as the inert gas, but as the inert gas, other than the Ar gas, for example, a rare gas may be used such as a helium (He) gas, a neon (Ne) gas, or a xenon (Xe) gas.

In a case where the source gas is caused to flow mainly from the gas supply pipe 310, mainly the gas supply pipe 310, the MFC 312, and the valve 314 constitute a source gas supply system, but the nozzle 410 may be included in the source gas supply system. The source gas supply system can also be referred to as a metal-containing gas supply system. In a case where the reducing gas is caused to flow from the gas supply pipe 320, mainly the gas supply pipe 320, the MFC 322, and the valve 324 constitute a reducing gas supply system, but the nozzle 420 may be included in the reducing gas supply system. In a case where the gas containing the group 15 element is caused to flow from the gas supply pipe 330, mainly the gas supply pipe 330, the MFC 332, and the valve 334 constitute a supply system for the gas containing the group 15 element, but the nozzle 430 may be included in the supply system for the gas containing the group 15 element. The metal-containing gas supply system, the reducing gas supply system, and the supply system for the gas containing the group 15 element can also be referred to as a processing gas supply system. The nozzles 410, 420, and 430 may be included in the processing gas supply system. Mainly the gas supply pipes 510, 520, and 530, the MFCs 512, 522, and 532, and the valves 514, 524, and 534 constitute an inert gas supply system.

In a gas supply method in the present embodiment, gas is transferred through the nozzles 410, 420, and 430 disposed in the preliminary chamber 201a inside a vertically long space having an annular shape defined by the inner wall of the inner tube 204 and end portions of a plurality of wafers 200. Then, the gas is ejected into the inner tube 204 from the plurality of gas supply holes 410a, 420a, and 430a of the nozzles 410, 420, and 430, the gas supply holes being provided at positions facing the wafers. More specifically, the source gas or the like is ejected in a direction parallel to the surfaces of the wafers 200 through the gas supply holes 410a of the nozzle 410, the gas supply holes 420a of the nozzle 420, and the gas supply holes 430a of the nozzle 430.

An exhaust hole (exhaust port) 204a is a through-hole formed in the side wall of the inner tube 204 at a position facing the nozzles 410, 420, and 430 and is, for example, a slit-shaped through-hole opened so as to be elongated in the vertical direction. The gas, which has been supplied into the process chamber 201 from the gas supply holes 410a, 420a, and 430a of the nozzles 410, 420, and 430 and has flowed on the surfaces of the wafers 200, flows into a gap (exhaust passage 206) formed between the inner tube 204 and the outer tube 203 through the exhaust hole 204a. Then, the gas that has flowed into the exhaust passage 206 flows into the first exhaust pipe 231 and is discharged to the outside of the processing furnace 202.

The exhaust hole 204a is provided at a position facing the plurality of wafers 200, and the gas supplied from the gas supply holes 410a, 420a, and 430a to the vicinity of the wafers 200 in the process chamber 201 flows in the horizontal direction and then flows into the exhaust passage 206 through the exhaust hole 204a. The exhaust hole 204a is not limited to being formed as a slit-shaped through-hole and may be formed by a plurality of holes.

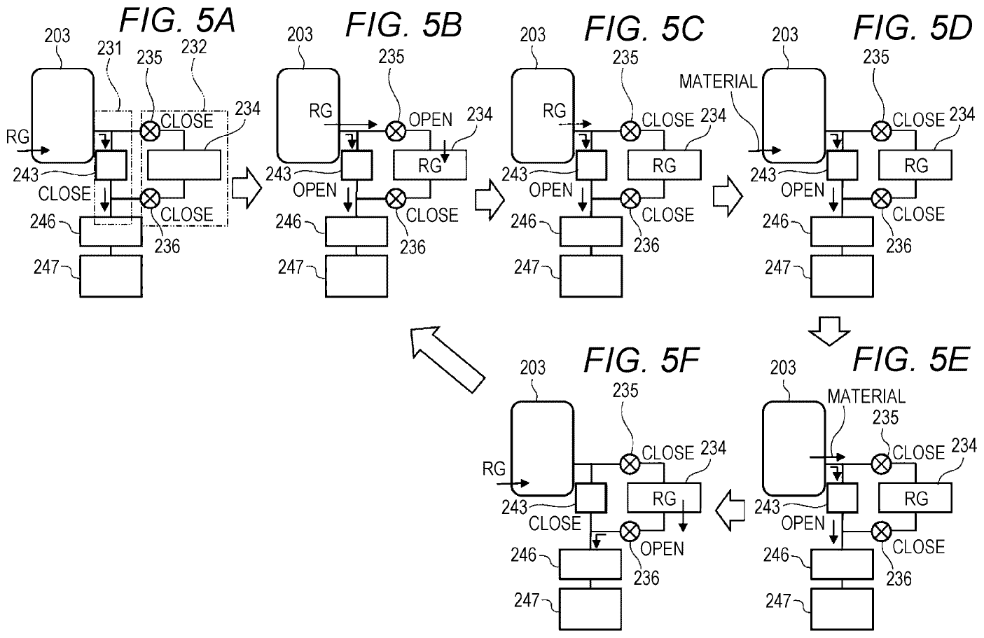

The manifold 209 is provided with the first exhaust pipe 231 that discharges an atmosphere in the process chamber 201. The first exhaust pipe 231 is connected to a vacuum pump 246 and the outer tube 203 (processing container). The first exhaust pipe 231 is connected to a pressure sensor 245 serving as a pressure detecting device (pressure detector) that detects a pressure in the process chamber 201, an auto pressure controller (APC) valve 243, and the pump 246 (vacuum pump 246) serving as an exhaust apparatus (vacuum exhaust apparatus) that exhausts an atmosphere in the processing container, in this order from the upstream side. The APC valve 243 can perform exhaust (vacuum exhaust) and exhaust stop (vacuum exhaust stop) of the inside of the process chamber 201 by opening and closing the valve in a state where the vacuum pump 246 is operated, and further, can regulate the pressure in the process chamber 201 by adjusting a degree of valve opening in a state where the vacuum pump 246 is operated. Mainly the exhaust hole 204a, the exhaust path 206, the first exhaust pipe 231, the APC valve 243, and the pressure sensor 245 constitute an exhaust system. The vacuum pump 246 may be included in the exhaust system. As illustrated in FIGS. 5A to 5F, a detoxifier 247 (exhaust gas processing apparatus) for processing and detoxifying the exhaust gas may be provided after the vacuum pump 246.

The second exhaust pipe 232 is connected to the vacuum pump 246 and the outer tube 203 (processing container) in parallel with the first exhaust pipe 231. The second exhaust pipe 232 is provided with the storage 234. The storage 234 is a buffer capable of temporarily storing gas, and includes, for example, a pressure container. The air supply valve 235 is provided on the air supply side of the storage 234 in the second exhaust pipe 232. The exhaust valve 236 is provided on the exhaust side of the storage 234.

Below the manifold 209, a seal cap 219 is provided serving as a furnace lid capable of airtightly closing a lower end opening of the manifold 209. The seal cap 219 is formed to abut against the lower end of the manifold 209 from the lower side in the vertical direction. The seal cap 219 includes a metal, for example, SUS or the like, and is formed in a disk shape. On the upper surface of the seal cap 219, an O-ring 220b is provided serving as a seal member abutting against the lower end of the manifold 209. On an opposite side of the seal cap 219 from the process chamber 201, a rotation mechanism 267 is installed that rotates the boat 217 that accommodates the wafers 200. A rotation shaft 255 of the rotation mechanism 267 penetrates the seal cap 219 and is connected to the boat 217. The rotation mechanism 267 is formed to rotate the wafers 200 by rotating the boat 217. The seal cap 219 is formed to be raised and lowered in the vertical direction by a boat elevator 115 serving as a raising/lowering mechanism vertically installed outside the outer tube 203. The boat elevator 115 is formed to be capable of loading the boat 217 into the process chamber 201 and unloading the boat 217 out of the process chamber 201 by raising and lowering the seal cap 219. The boat elevator 115 is formed as a transfer device (a transfer mechanism, a transfer system) that transfers the boat 217 and the wafers 200 accommodated in the boat 217 to the inside and the outside of the process chamber 201.

The boat 217 is formed so that a plurality of, for example, 25 to 200 wafers 200 are arranged at intervals in the vertical direction in a horizontal posture in a state where the centers thereof are aligned with each other. The boat 217 includes, for example, a heat-resistant material such as quartz or SiC. In a lower portion of the boat 217, dummy substrates 218 including a heat-resistant material, for example, quartz or SiC, are supported in multiple stages in a horizontal posture. With this configuration, heat from the heater 207 is less likely to be transferred to the seal cap 219 side. Note that the present embodiment is not limited to the above-described form. For example, a heat insulating tube formed as a cylindrical member including a heat-resistant material such as quartz or SiC may be provided without provision of the dummy substrates 218 at the lower portion of the boat 217.

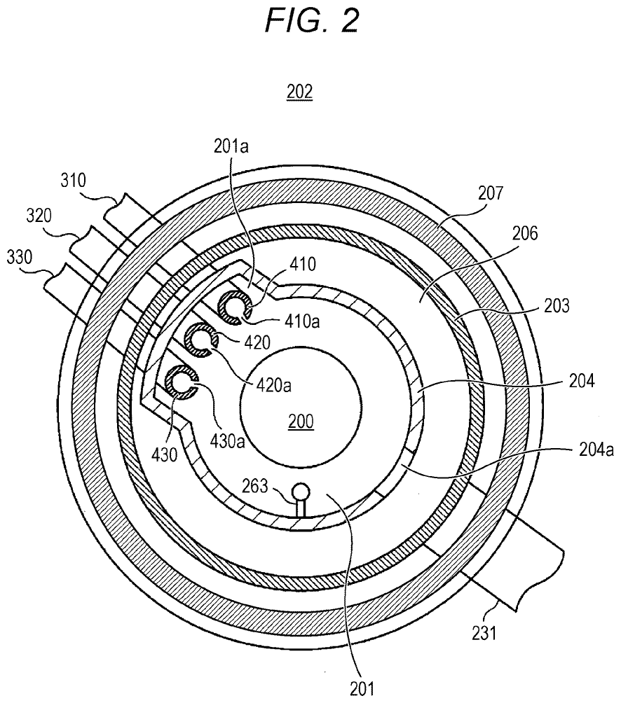

As illustrated in FIG. 2, a temperature sensor 263 serving as a temperature detector is installed in the inner tube 204 and is formed so that a temperature in the process chamber 201 has a desired temperature distribution by regulation of an energization amount to the heater 207 based on temperature information detected by the temperature sensor 263. The temperature sensor 263 is formed in an L-shape similarly to the nozzles 410, 420, and 430 and is provided along the inner wall of the inner tube 204.

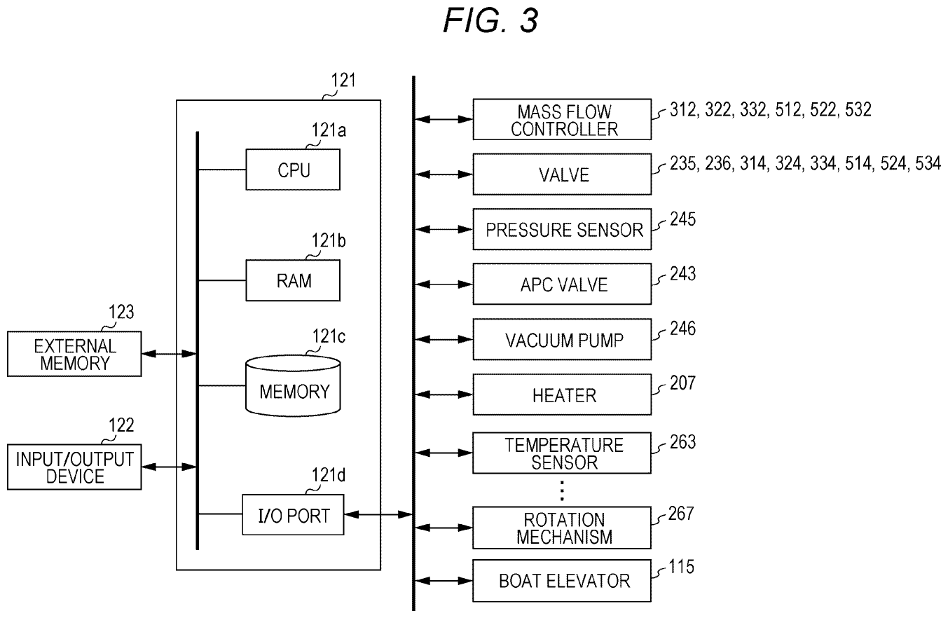

As illustrated in FIG. 3, the controller 121 that is a controller (control means) is configured as a computer provided with a central processing unit (CPU) 121a, a random access memory (RAM) 121b, a memory 121c, and an I/O port 121d. The RAM 121b, the memory 121c, and the I/O port 121d are formed to be capable of exchanging data with the CPU 121a via an internal bus. The controller 121 is connected to an input/output device 122 formed as, for example, a touch panel or the like.

The memory 121c includes, for example, a flash memory, a hard disk drive (HDD), or the like. The memory 121c readably stores a control program that controls operation of the substrate processing apparatus, a process recipe in which procedure, a condition, and the like, of a method of manufacturing a semiconductor device (a method of processing a substrate) described later are described, and the like. The process recipe is a combination made so as to cause the controller 121 to execute steps in the method of manufacturing a semiconductor device (the method of processing a substrate) described later to obtain a predetermined result, and functions as a program. Hereinafter, the process recipe, the control program, and the like, are also collectively and simply referred to as a program. In the present description, the term “program” may include only the process recipe alone, only the control program alone, or a combination of the process recipe and the control program. The RAM 121b is formed as a memory area (work area) in which programs, data, and the like read by the CPU 121a are temporarily held.

The I/O port 121d is connected to the MFCs 312, 322, 332, 512, 522, and 532, the air supply valve 235, the exhaust valve 236, the valves 314, 324, 334, 514, 524, and 534, the pressure sensor 245, the APC valve 243, the vacuum pump 246, the heater 207, the temperature sensor 263, the rotation mechanism 267, the boat elevator 115, and the like described above.

The CPU 121a is configured to read the control program from the memory 121c to execute the control program and to read a recipe, and the like, from the memory 121c in response to an input of an operation command from the input/output device 122, and the like. The CPU 121a is configured to be capable of controlling: flow rate regulation operations of various gases by the MFCs 312, 322, 332, 512, 522, and 532; opening/closing operations of the air supply valve 235, the exhaust valve 236, the valves 314, 324, 334, 514, 524, and 534; opening/closing operations of the APC valve 243, and a pressure regulation operation based on the pressure sensor 245 by the APC valve 243; a temperature regulation operation of the heater 207 based on the temperature sensor 263; start and stop of the vacuum pump 246; rotation and rotation speed adjustment operations of the boat 217 by the rotation mechanism 267; raising/lowering operations of the boat 217 by the boat elevator 115; an accommodating operation of the wafers 200 into the boat 217; and the like, according to the content of the read recipe.

The controller 121 can be configured by installation, onto a computer, of the above-described program stored in an external memory (for example, a magnetic tape, a magnetic disk such as a flexible disk or a hard disk, an optical disk such as a CD or a DVD, a magneto-optical disk such as an MO disk, or a semiconductor memory such as a USB memory or a memory card) 123. The memory 121c and the external memory 123 are formed as computer-readable recording media. Hereinafter, the memory 121c and the external memory 123 are collectively and simply referred to as a recording medium. In the present description, the term “recording medium” may include only the memory 121c alone, only the external memory 123 alone, or both of them. A program may be provided to a computer by use of a communication means such as the Internet or a dedicated line without use of the external memory 123.

The controller 121 is configured to be capable of causing the first exhaust pipe 231, the second exhaust pipe 232, and the gas supplier to execute:
(a) processing of supplying the first processing gas into the processing container (process chamber 201) in a state where the exhaust of the atmosphere in the processing container is stopped (FIG. 5A);
(b) processing of exhausting the atmosphere in the processing container to the first exhaust pipe 231 and the storage 234 of the second exhaust pipe 232 in a state where the exhaust valve 236 is closed and the air supply valve 235 is opened, after (a) (FIG. 5B);
(c) processing of exhausting the atmosphere in the processing container by the first exhaust pipe 231 in a state where the air supply valve 235 is closed to stop the exhaust of the atmosphere in the processing container by the storage 234, after (b) (FIG. 5C);
(d) processing of supplying the second processing gas into the processing container in a state where the air supply valve 235 is closed to stop the exhaust of the atmosphere in the processing container by the storage 234, after (c) (FIG. 5D); and
(e) processing of performing (a) to (d) to process the substrate (wafer 200) in the processing container.

Further, the controller 121 may perform processing (f) below, or may perform (g) after (f). (f) exhausting the atmosphere in the processing container by the first exhaust pipe 231 in a state where the air supply valve 235 and the exhaust valve 236 are closed to stop the exhaust of the atmosphere in the processing container by the storage 234, after (d)
(g) exhausting the atmosphere in the storage 234 to the exhaust apparatus (pump 246 (vacuum pump 246)) in a state where the exhaust of the atmosphere in the processing container by the first exhaust pipe 231 is stopped and the exhaust valve 236 is opened.

Here, (a), (b), (c), (d), and (f) may be performed in (e), or (a), (b), (c), (d), (f), and (g) may be performed in (e). In addition, (a) to (d) may be performed a predetermined number of times in (e).

In (g), a degree of opening of the exhaust valve 236 may be controlled so that the exhaust amount from the storage 234 to the exhaust apparatus (vacuum pump 246) is a predetermined exhaust amount. The processing of (g) may be performed before (a), or may be performed in parallel with (a). In (g), the inside of the storage 234 may be exhausted to a reduced pressure atmosphere. In other words, the exhaust may be performed until a pressure in the storage 234 is lower than the pressure in the process chamber 201.

### (2) Substrate Processing Step

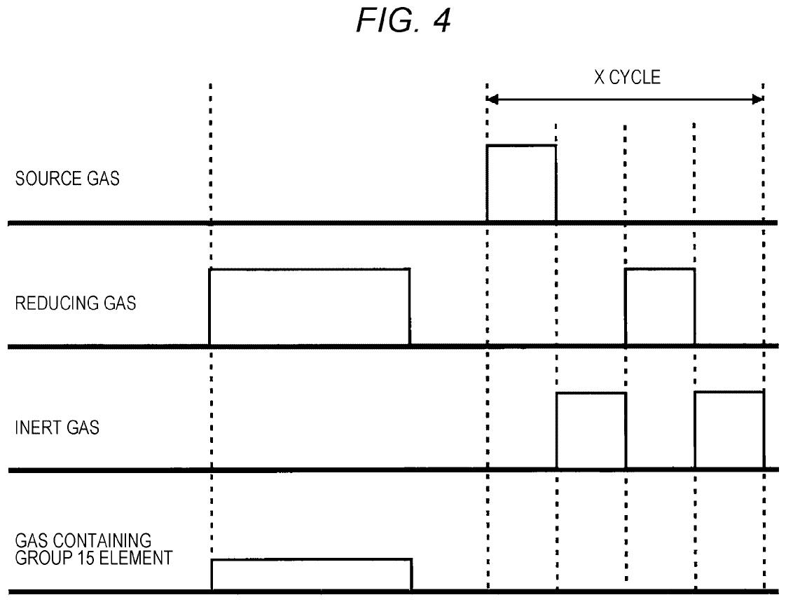

As one of steps of manufacturing a semiconductor device (device), an example will be described of a step of forming a Mo-containing film containing molybdenum (Mo) used as, for example, a control gate electrode of a 3D NAND on the wafer 200, with reference to FIG. 4. The step of forming the Mo-containing film is executed using the processing furnace 202 of the substrate processing apparatus 10 described above. In the following description, operations of sections constituting the substrate processing apparatus 10 are controlled by the controller 121.

In the substrate processing step (semiconductor device manufacturing step) according to the present embodiment,
(A) supplying a gas containing a group 15 element to the wafer 200 to form a first layer containing the group 15 element on the surface of the wafer 200;
(B) supplying a gas containing a Mo element to the wafer 200;
(C) supplying a reducing gas serving as a reactant gas to the wafer 200; and
(D) performing (B) and (C) a predetermined number of times in an atmosphere that suppresses decomposition of the first layer to form a film containing the Mo element on the first layer, are performed to form the Mo-containing film serving as a metal-containing film on the first layer of the wafer 200.

In the present description, the term “wafer” may mean a “wafer itself” or a “laminate of a wafer and a predetermined layer, film, or the like formed on a surface of the wafer”. In the present description, the term “surface of a wafer” may mean a “surface of a wafer itself” or a “surface of a predetermined layer, film, or the like formed on the wafer”. In the present description, the term “substrate” is synonymous with the word “wafer”.

### (Wafer Loading)

When a plurality of wafers 200 is loaded into the boat 217 (wafer charge), as illustrated in FIG. 1, the boat 217 supporting the plurality of wafers 200 is lifted and loaded into the process chamber 201 (boat loading) by the boat elevator 115 and accommodated in the processing container. In this state, the seal cap 219 closes a lower end opening of the outer tube 203 with the O-ring 220b interposed therebetween.

### (Pressure Regulation and Temperature Regulation)

The vacuum pump 246 performs vacuum exhaust so that the inside of the process chamber 201, that is, a space where the wafers 200 are present has a desired pressure (degree of vacuum). At this time, the pressure in the process chamber 201 is measured by the pressure sensor 245, and the APC valve 243 is feedback-controlled on the basis of the measured pressure information (pressure regulation). The vacuum pump 246 maintains a state of being constantly operated at least until the processing on the wafers 200 is completed. The inside of the process chamber 201 is heated by the heater 207 so as to have a desired temperature. At this time, the energization amount to the heater 207 is feedback-controlled on the basis of the temperature information detected by the temperature sensor 263 so that the inside of the process chamber 201 has a desired temperature distribution (temperature regulation). The inside of the process chamber 201 is continuously heated by the heater 207 at least until the processing on the wafers 200 is completed.

### [Step of Forming First Layer]

### [First Step]

### (Pre-treatment Step; Supplying Gas Containing Group 15 Element)

The valve 334 is opened to cause a gas containing a group 15 element to flow into the gas supply pipe 330. The gas containing the group 15 element is subjected to flow rate regulation by the MFC 332, supplied from the gas supply holes 430a of the nozzle 430 into the process chamber 201, and exhausted from the first exhaust pipe 231. At this time, the gas containing the group 15 element is supplied to the wafers 200. At this time, the valve 534 may be opened to cause an inert gas such as Ar gas into the gas supply pipe 530. The Ar gas flowing through the gas supply pipe 530 is subjected to flow rate regulation by the MFC 532, supplied into the process chamber 201 together with the gas containing the group 15 element, and exhausted from the first exhaust pipe 231. At this time, in order to prevent the gas containing the group 15 element from entering the nozzles 410 and 420, the valves 514 and 524 are opened, and the Ar gas is caused to flow into the gas supply pipes 510 and 520. The Ar gas is supplied into the process chamber 201 through the gas supply pipes 310 and 320 and the nozzles 410 and 420, and is exhausted from the first exhaust pipe 231.

At this time, the APC valve 243 is regulated to set the pressure in the process chamber 201 to a pressure within a range of 1 to 3990 Pa, for example, 1000 Pa. A supply flow rate of the gas containing the group 15 element controlled by the MFC 332 is, for example, a flow rate within a range of 0.01 to 5.0 slm. Supply flow rates of the Ar gases controlled by the MFCs 512, 522, and 532 are set to, for example, a flow rate within a range of 0.1 to 5.0 slm in order to suppress entry of the gas containing the group 15 element into the respective nozzles. At this time, a temperature of the heater 207 is set to a temperature at which a temperature of the wafer 200 is, for example, within a range of 300 to 650° C. The temperature of the wafer 200 is preferably set to a temperature less than or equal to a temperature in a step of forming the metal-containing film described later. Note that expression of a numerical range such as “1 to 3990 Pa” in the present disclosure means that the lower limit value and the upper limit value are included in the range. Thus, for example, “1 to 3990 Pa” means “greater than or equal to 1 Pa and less than or equal to 3990 Pa”. The same applies to other numerical ranges.

(Supply of at least One or More of Dilution Gas and Reducing Gas)

In addition, there is a timing of supplying at least one or more of a dilution gas and a reducing gas while supplying the gas containing the group 15 element. Here, as the dilution gas, a reducing gas can be used in addition to an inert gas. Preferably, it is possible to use a gas having a characteristic of suppressing a state change and decomposition of a material containing the group 15 element. Such a gas is supplied into the process chamber 201, whereby the inside of the process chamber 201 is set to an atmosphere that suppresses a state change and decomposition of the gas containing the group 15 element. To supply these gases, specifically, the valve 324 is opened, and a reducing gas that is a dilution gas is supplied to the gas supply pipe 320. The reducing gas is subjected to flow rate regulation by the MFC 322, supplied from the gas supply holes 420a of the nozzle 420 into the process chamber 201, and exhausted from the first exhaust pipe 231. At this time, the gas containing the group 15 element and the reducing gas serving as the dilution gas are supplied to the wafers 200. At the same time, the valve 524 may be opened to cause the inert gas such as Ar gas to flow into the gas supply pipe 520. The Ar gas flowing through the gas supply pipe 520 is subjected to flow rate regulation by the MFC 522, supplied into the process chamber 201 together with the reducing gas, and exhausted from the first exhaust pipe 231. In a case where only the inert gas is supplied as the dilution gas, it is sufficient that the valve 324 is closed to supply the inert gas from another inert gas supply system.

### (Regulation of Concentration of Material Containing Group 15 Element)

Note that a dilution gas may be supplied in order to regulate a concentration of the material containing the group 15 element supplied to the wafers 200 to a predetermined concentration. The gas containing the group 15 element may be a gas composed of a single substance of the material containing the group 15 element, or the gas of the material containing the group 15 element and the dilution gas may be mixed, and in each case, at least one or more of a flow rate of the gas containing the group 15 element, a flow rate of the reducing gas, and a flow rate of the dilution gas are regulated so that a predetermined concentration is obtained. Here, the flow rate of each gas is regulated so that the concentration of the material containing the group 15 element (gas containing the group 15 element) is, for example, in a range of 0.1 to 50%. By supplying the gas having such a concentration, it is possible to form the first layer containing the group 15 element. In addition, it is possible to suppress an increase in the concentration of the group 15 element in the metal film (Mo-containing film) formed on the first layer. When the concentration is less than 0.1%, it is difficult to form the first layer containing the group 15 element, a formation time of the first layer increases, and production throughput may decrease. When the concentration exceeds 50%, the concentration of the group 15 element in the first layer increases, the concentration of the group 15 element in the metal film (Mo-containing film) increases, and characteristics of the metal film may deteriorate. By supply of the gas having a concentration exceeding 50%, an amount of a decomposition product of the material containing the group 15 element generated in the process chamber 201 increases, a ratio of the group 15 element to another element (for example, hydrogen) in the first layer is not a predetermined ratio, and there is a possibility that it is difficult to obtain an effect described in the present disclosure.

At this time, the gas flowing into the process chamber 201 is a gas containing at least the group 15 element. Here, the group 15 element includes at least one or more of phosphorus (P) and arsenic (As). The gas containing the group 15 element is a gas containing at least one or more of P and As. Preferably, the gas containing the group 15 element can contain hydrogen (H). As such a gas containing P and H include, for example, it is possible to use: alkylphosphine—based gases such as a trimethylphosphine ((CH₃)₃P) gas, a triethylphosphine ((C₂H₅)₃P) gas, a tri-n-propylphosphine ((n-C₃H₇)₃P) gas, a triisopropylphosphine ((i-C₃H₇)₃P) gas, a tri-n-butylphosphine ((n-C₄H₉)₃P) gas, a triisobutylphosphine ((i-C₄H₉)₃P) gas, a tritertiarybutylphosphine ((t-C₄H₉)₃P) gas, and a tertiarybutylphosphine (t-C₄H₉PH₂) gas; aminophosphine—based gases such as an aminophosphine (NH₂PH₂) gas, a tris(dimethylamino)phosphine ([(CH₃)₂N]₃P) gas, bis(dimethylamino)phosphine (PH[N(CH₃)₂]₂) gas, and bis(dimethylamino) chlorophosphine ([(CH₃)₂N]₂PCl) gas; phosphinamide—based gases such as bis(dimethylamino)methylphosphine (CH₃P[N(CH₃)₂]₂) gas, dimethylaminodimethylphosphine ((CH₃)₂PN(CH₃)₂) gas, and diethylaminodiethylphosphine ((C₂H₅)₂PN(C₂H₅)₂) gas; phosphine—based gases such as phosphine (PH₃) gas, and diphosphine (P₂H₄) gas; trivinylphosphine (((CH₂═CH)₃P) gas; and the like. The material containing the group 15 element includes at least one or more of these materials, and the gas containing the group 15 element may be a single gas of the material containing the group 15 element, or a mixed gas of the material containing the group 15 element and the dilution gas.

By supply of such a gas to the wafer 200, the first layer containing at least P is formed on the surface of the wafer 200. Preferably, the first layer is a layer containing P and H. More preferably, the first layer is a layer containing a molecule of the material containing the group 15 element or a substance in a state in which the molecule of the material containing the group 15 element is partially decomposed. For example, the first layer formed in a case where PH₃ is used as the material containing the group 15 element may contain P, H, and PHx. Here, X is an integer of less than or equal to 3, and PHx includes, for example, at least one or more of PH, PH₂, and PH₃. In order to form the first layer containing such a substance, the temperature in the process chamber 201 is preferably a temperature at which a part of the material containing the group 15 element can be decomposed. For example, in a case where PH₃ is used as the material containing the group 15 element, the temperature in the process chamber 201 is in a range of 300° C. to 650° C.

### [Second Step]

### (Residual Gas Removal)

After a lapse of a predetermined time from the start of the supply of the gas containing the group 15 element, for example, 1 to 600 seconds later, the valve 334 of the gas supply pipe 330 is closed to stop the supply of the gas containing the group 15 element. That is, the time for which the gas containing the group 15 element is supplied to the wafer 200 is in a range of, for example, 1 to 600 seconds. At this time, while the APC valve 243 of the first exhaust pipe 231 is kept open, the inside of the process chamber 201 is vacuum-exhausted by the vacuum pump 246, and the gas containing the group 15 element that remains in the process chamber 201 and is unreacted or has contributed to the formation of the first layer is excluded from the inside of the process chamber 201. That is, the atmosphere in the process chamber 201 is exhausted. By lowering the pressure in the process chamber 201, it is possible to exhaust the gas containing the group 15 element remaining in the gas supply pipe 330 and the nozzle 430. By exhausting the gas containing the group 15 element remaining in the gas supply pipe 330 and the nozzle 430, it is possible to suppress the gas containing the group 15 element remaining in the gas supply pipe 330 and the nozzle 430 from being supplied into the process chamber 201 in the step of forming the metal-containing film. At this time, the supply of the Ar gas into the process chamber 201 may be maintained while the valves 514, 524, and 534 are kept open. The Ar gas acts as a gas suppressing entry of a gas to each nozzle, and can act as a purge gas. In a case where the Ar gas is supplied as the purge gas, it is possible to enhance an effect of excluding the gas containing the group 15 element that remains in the process chamber 201 and is unreacted or has contributed to the formation of the first layer from the inside of the process chamber 201.

### [Step of Forming Metal-Containing Film]

### [Third Step]

### (Metal-containing Gas Supply)

Next, the valve 314 is opened to cause the metal-containing gas, which is a source gas, to flow into the gas supply pipe 310. The metal-containing gas is subjected to flow rate regulation by the MFC 312, supplied from the gas supply holes 410a of the nozzle 410 into the process chamber 201, and exhausted from the first exhaust pipe 231. At this time, the metal-containing gas is supplied to the wafers 200. At this time, the valve 514 is simultaneously opened to cause the inert gas such as Ar gas to flow into the gas supply pipe 510. The Ar gas flowing through the gas supply pipe 510 is subjected to flow rate regulation by the MFC 512, supplied into the process chamber 201 together with the metal-containing gas, and exhausted from the first exhaust pipe 231. At this time, the valves 524 and 534 are opened to cause the Ar gas to flow into the gas supply pipes 520 and 530, in order to prevent entering of the metal-containing gas into the nozzles 420 and 430. The Ar gas is supplied into the process chamber 201 through the gas supply pipes 320 and 330 and the nozzles 420 and 430 and is exhausted from the first exhaust pipe 231.

At this time, the APC valve 243 is regulated to set the pressure in the process chamber 201 to a pressure within a range of 1 to 3990 Pa, for example, 500 Pa. A supply flow rate of the metal-containing gas controlled by the MFC 312 is, for example, 0.1 to 1.0 slm. Each of the supply flow rates of the Ar gases controlled by the MFCs 512, 522, and 532 is set in a range of, for example, 0.1 to 5.0 slm. At this time, a temperature of the heater 207 is set to a temperature at which a temperature of the wafer 200 is, for example, within a range of 300 to 650° C.

At this time, a main gas (gas supplied to the wafer 200) flowing into the process chamber 201 is the metal-containing gas. That is, the metal-containing gas is supplied to the wafer 200. Here, as the metal-containing gas, for example, it is possible to use a molybdenum (Mo)—containing gas containing molybdenum (Mo) serving as a metal element. As the Mo-containing gas, it is possible to use a gas containing Mo and chlorine (Cl), for example, a molybdenum trichloride (MoCl₃) gas, a molybdenum tetrachloride (MoCl₄) gas, a molybdenum pentachloride (MoCl₅) gas, or a molybdenum hexachloride (MoCl₆) gas, or a gas containing Mo, oxygen (O), and Cl, for example, a molybdenum dioxide dichloride (MoO₂Cl₂), or molybdenum tetrachloride oxide (MoOCl₄). By supply of the Mo—containing gas, a Mo—containing layer serving as a metal-containing layer is formed on the wafer 200 (first layer). In a case where MoCl₅ is used, the Mo—containing layer may be a Mo layer containing Cl or a MoCl₅ adsorption layer. In a case where MoO₂Cl₂ (or MoOCl₄) is used, the Mo—containing layer may be a Mo layer containing Cl or O, may be a MoO₂Cl₂ (or MoOCl₄) adsorption layer, or may contain both of them. Preferably, the Mo layer is a layer containing P contained in the first layer. For example, in a case where P, H, or PHx is contained in the first layer, the Mo—containing gas reacts with the molecules constituting the first layer, and the elements and molecules constituting the first layer are desorbed from the first layer. In this desorption process, elements and molecules constituting the first layer can be incorporated into the Mo layer.

### [Fourth Step]

### (Residual Gas Removal)

After a lapse of a predetermined time from the start of the supply of the metal-containing gas, for example, 1 to 60 seconds later, the valve 314 of the gas supply pipe 310 is closed to stop the supply of the metal-containing gas. That is, the time for which the metal-containing gas is supplied to the wafer 200 is in a range of, for example, 1 to 60 seconds. At this time, while the APC valve 243 of the first exhaust pipe 231 is kept open, the inside of the process chamber 201 is vacuum-exhausted by the vacuum pump 246, and the metal-containing gas that remains in the process chamber 201 and is unreacted or has contributed to the formation of the metal-containing layer is excluded from the inside of the process chamber 201. That is, the atmosphere in the process chamber 201 is exhausted. At this time, the supply of the Ar gas into the process chamber 201 may be maintained while the valves 514, 524, and 534 are kept open. The Ar gas acts as a gas suppressing entry of a gas to each nozzle, and can act as a purge gas. In a case where the Ar gas is supplied as the purge gas, it is possible to enhance an effect of excluding the metal-containing gas that remains in the process chamber 201 and is unreacted or has contributed to the formation of the metal-containing layer from the inside of the process chamber 201.

### [Fifth Step]

### (Reducing Gas Supply)

After the residual gas in the process chamber 201 is removed, the valve 324 is opened to cause the reducing gas to flow into the gas supply pipe 320. The reducing gas is subjected to flow rate regulation by the MFC 322, supplied from the gas supply holes 420a of the nozzle 420 into the process chamber 201, and exhausted from the first exhaust pipe 231. At this time, the reducing gas is supplied to the wafers 200. At this time, the supply of the Ar gas into the gas supply pipes 510, 520, and 530 is maintained while the valves 514, 524, and 534 are kept open. The Ar gases flowing through the gas supply pipes 510, 520, and 530 are subjected to flow rate regulation by the MFCs 512, 522, and 532, respectively. The Ar gas flowing through the gas supply pipe 520 is supplied into the process chamber 201 through the gas supply pipe 320 and the nozzle 420 together with the reducing gas, and is exhausted from the first exhaust pipe 231. The Ar gas flowing through the gas supply pipe 530 is supplied into the process chamber 201 through the gas supply pipe 330 and the nozzle 430, and is exhausted from the first exhaust pipe 231. The Ar gas flowing through the gas supply pipe 510 is supplied into the process chamber 201 through the gas supply pipe 310 and the nozzle 410, is exhausted from the first exhaust pipe 231, and prevents entering of the reducing gas into the nozzle 410.

At this time, the APC valve 243 is regulated to set the pressure in the process chamber 201 to a pressure within a range of 1 to 133000 Pa, for example, 5000 Pa. A supply flow rate of the reducing gas controlled by the MFC 322 is in a range of, for example, 1 to 50 slm, preferably, in a range of 15 to 40 slm. Each of the supply flow rates of the Ar gases controlled by the MFCs 512, 522, and 532 is set in a range of, for example, 0.1 to 5.0 slm. At this time, a temperature of the heater 207 is set to a temperature at which a temperature of the wafer 200 is, for example, within a range of 300 to 650° C.

At this time, a main gas flowing into the process chamber 201 is a reducing gas serving as reactant gas. That is, the reducing gas is supplied to the wafer 200.

In the case of an amount of supply of the reducing gas as described above, a desired reduction reaction can be obtained. That is, a deposition rate of a film on the wafer 200 can be improved, and a film having desired characteristics can be obtained. On the other hand, in a case where the reducing gas is supplied in this way, there may be a problem that it takes a long time to exhaust the reducing gas. In addition, depending on a type (characteristic) of the reducing gas, there may be a problem that the pump 246 cannot perform exhaust at a time.

Here, the reducing gas is, for example, a gas including hydrogen (H). The gas is preferably a gas composed of hydrogen alone. Specifically, hydrogen (H₂) gas or deuterium (D₂) can be used. Hereinafter, as an example, a case will be described where H₂ gas is used as the reducing gas.

### [Sixth Step]

### (Residual Gas Removal)

After a lapse of a predetermined time from the start of the supply of the reducing gas, for example, 1 to 1200 seconds later, the valve 324 of the gas supply pipe 320 is closed to stop the supply of the reducing gas. Then, the reducing gas that remains in the process chamber 201 and is unreacted or has contributed to the formation of the metal-containing layer, and a reaction by-product are excluded from the process chamber 201 by a processing procedure similar to that in the second step described above. That is, the atmosphere in the process chamber 201 is exhausted.

### (Execution of Predetermined Number of Times)

A cycle of sequentially performing the third step to the sixth step described above is performed at least one or more times (predetermined number of times (n times, n is an integer of greater than or equal to 1), to form a Mo—containing film serving as a metal-containing film having a predetermined thickness on the wafer 200. The above-described cycle is preferably repeated a plurality of times. The Mo—containing film is a film containing molybdenum as a main component, and a layer containing Mo and P is formed on the wafer 200 side (first layer side) of the Mo—containing film. Preferably, a P concentration in the Mo—containing film is made to decrease toward the surface of the Mo—containing film.

### (After-purge and Atmospheric Pressure Restoration)

The Ar gas is supplied from each of the gas supply pipes 510, 520, and 530 into the process chamber 201, and is exhausted from the first exhaust pipe 231. The Ar gas acts as a purge gas, whereby the inside of the process chamber 201 is purged with the inert gas, and a gas remaining in the process chamber 201 and a reaction by-product are removed from the inside of the process chamber 201 (after-purge). Thereafter, the atmosphere in the process chamber 201 is replaced with the inert gas (inert gas replacement), so that the pressure in the process chamber 201 is restored to a normal pressure (atmospheric pressure restoration).

### (Wafer Unloading)

Then, the seal cap 219 is lowered by the boat elevator 115, and the lower end of the outer tube 203 is opened. Then, the processed wafers 200 are unloaded (boat unloading) in a state of being supported by the boat 217 from the lower end of the outer tube 203 to the outside of the outer tube 203. Thereafter, the processed wafers 200 are taken out from the boat 217 (wafer discharge).

### (3) Effects According to Present Embodiment

According to the present embodiment, one or more effects described below can be obtained.
(A) By forming the first layer between the surface of the wafer 200 and the Mo—containing film, it is possible to improve adhesion between the Mo—containing film and the wafer 200. As a result, a metal-based film having good film characteristics can be formed without formation of a barrier film on the surface of the wafer 200.
(B) By including the group 15 element contained in the first layer in the Mo—containing film, it is possible to improve adhesion to a film (base film) formed on the surface of the wafer 200. That is, it is possible to increase bonding strength between the first layer and the surface of the wafer 200 and bonding strength between the first layer and the Mo—containing film.
(C) By diffusing the group 15 element contained in the first layer into the Mo—containing film, it is possible to improve the bonding strength between elements present in the Mo—containing film. That is, bonding occurs between the Mo elements or between the Mo element and the group 15 element.
(D) It is possible to enhance reactivity between the first layer and the Mo—containing gas serving as the metal-containing gas, and improve a deposition rate of the Mo—containing film. That is, it is possible to improve productivity (throughput) of the semiconductor device. A case will be described where PH₃ gas is used as the gas containing the group 15 element, for example, and MoO₂Cl₂ is used as the Mo—containing gas, for example. In this case, a layer containing PHx is formed as the first layer. The PHx and MoO₂Cl₂ are likely to cause a chemical reaction, and react easily as compared with a case where the first layer is not formed on the surface of the wafer 200, and on the wafer 200 (on the first layer), a layer containing Mo is formed, and molecules containing P are desorbed from the first layer. Examples of the molecule containing P include polonium tetrachloride (POCl₄). Since such a reaction occurs, it is possible to improve the deposition rate of the Mo—containing film. By the chemical reaction, the group 15 element is incorporated into the Mo—containing film (the group 15 element is diffused into the Mo—containing film). It can also be said that a part (surface) of the first layer is partially removed by the source gas (metal-containing gas). It can also be said that a part (surface) of the first layer is partially decomposed by the source gas.
(E) At the time of forming the first layer, even in a state where the temperature of the wafer 200 and members around the wafer 200 (for example, at least one or more of the support and the processing container) is a decomposition temperature of the material containing the group 15 element, it is possible to suppress excessive decomposition of the material containing the group 15 element by supplying the dilution gas. That is, by supplying the dilution gas, it is possible to form an atmosphere that suppresses decomposition of the material containing the group 15 element. In addition, even if the material containing the group 15 element is decomposed in the process chamber 201, it is possible to suppress, by the dilution gas, excessive supply of the decomposition product to the wafers 200. That is, an effect is obtained of pushing away the decomposition product by the dilution gas. It is considered that the dilution gas can suppress the decomposition of the material containing the group 15 element by lowering a partial pressure of the gas containing the group 15 element. In addition, by lowering the partial pressure of the gas containing the group 15 element, it is possible to lower a probability that molecules of the gas containing the group 15 element collide with a member (for example, the support or the processing container) having a temperature greater than or equal to the decomposition temperature. As a result, it is considered that the probability can be lowered that the molecules of the gas containing the group 15 element receive thermal energy from the member having the temperature greater than or equal to the decomposition temperature and are decomposed. A similar effect can be obtained not only by the partial pressure of the gas containing the group 15 element but also by the total pressure. In the substrate processing apparatus having the heater around the processing container as illustrated in FIG. 1, the temperature of the members present around the wafer 200 may be higher than a set temperature of the wafer 200, and there is an environment in which such decomposition of the material containing the group 15 element is likely to occur. Thus, with such a configuration of the substrate processing apparatus, a more remarkable effect can be obtained. Preferably, the partial pressure of the gas containing the group 15 element in the process chamber 201 is smaller than a partial pressure of the inert gas serving as the dilution gas. Such a partial pressure relationship makes it possible to suppress decomposition of the gas containing the group 15 element.
(F) At the time of forming the first layer, even in a state where the temperature of the wafer 200 and the members around the wafer 200 (for example, at least one or more of the support and the processing container) is the decomposition temperature of the material containing the group 15 element, it is possible to suppress excessive decomposition of the material containing the group 15 element by supplying the reducing gas. That is, by supplying the reducing gas, it is possible to form an atmosphere that suppresses decomposition of the material containing the group 15 element. It is considered that the reducing gas itself has an effect similar to that of the dilution gas and also has an action of suppressing thermal decomposition of the material containing the group 15 element. In order to obtain a mechanism in which the reducing gas directly suppresses the thermal decomposition of the material containing the group 15 element as described above, it is preferable that both the gas containing the group 15 element and the reducing gas contain the same element. Examples of such an element include hydrogen (H). Specific examples of the material include the materials described above. Preferably, the partial pressure of the gas containing the group 15 element in the process chamber 201 is smaller than a partial pressure of the reducing gas. Such a partial pressure relationship makes it possible to suppress decomposition of the gas containing the group 15 element. In order to obtain such a partial pressure, for example, as illustrated in FIG. 4, it is sufficient that the flow rate of the reducing gas is larger than the flow rate of the gas containing the group 15 element.
(G) By forming the metal film (Mo—containing film) in an atmosphere that suppresses decomposition of the first layer, it is possible to obtain at least one or more of the effects of (A), (B), (C), and (D).

### (4) Reactant Gas Exhaust Step

The substrate processing step (semiconductor device manufacturing step) according to the present embodiment may be performed as follows in order to solve the problem that occurs in a case where the amount of supply of the reducing gas serving as the reactant gas is large.

In FIG. 5, in the substrate processing step, performed are:
(a) processing of supplying the first processing gas (reducing gas) serving as a reactant gas RG into the processing container (process chamber 201) in a state where the exhaust of the atmosphere in the processing container is stopped (FIG. 5A);
(b) processing of exhausting the atmosphere in the processing container to the first exhaust pipe 231 and the storage 234 of the second exhaust pipe 232 in a state where the exhaust valve 236 is closed and the air supply valve 235 is opened, after (a) (FIG. 5B);
(c) processing of exhausting the atmosphere in the processing container by the first exhaust pipe 231 in a state where the air supply valve 235 is closed to stop the exhaust of the atmosphere in the processing container by the storage 234, after (b) (FIG. 5C);
(d) processing of supplying the second processing gas (source gas) into the processing container in a state where the air supply valve 235 is closed to stop the exhaust of the atmosphere in the processing container by the storage 234, after (c) (FIG. 5D); and
(e) processing of performing (a) to (d) to process the substrate (wafer 200) in the processing container.

Further, the following pieces of processing (f) and (g) may be performed.
(f) Processing of exhausting the atmosphere in the processing container by the first exhaust pipe 231 in a state where the air supply valve 235 and the exhaust valve 236 are closed to stop the exhaust of the atmosphere in the processing container by the storage 234, after (d) (FIG. 5E)
(g) Processing of exhausting the atmosphere in the storage 234 to the vacuum exhaust apparatus (vacuum pump 246) in a state where the exhaust of the atmosphere in the processing container by the first exhaust pipe 231 is stopped and the exhaust valve 236 is opened (FIG. 5F)

Here, the first processing gas supplied to the process chamber 201 in the processing (a) is, for example, a reducing gas, specifically, a high-pressure H₂ gas. The supply of the first processing gas is performed similarly to that in the fifth step described above. In the processing of (a), both the air supply valve 235 and the exhaust valve 236 of the storage 234 are closed.

In the processing of (b), the air supply valve 235 of the storage 234 is opened, and the exhaust valve 236 on the exhaust side is closed. As a result, a part of the atmosphere in the processing container can be exhausted to the storage 234.

In the processing of (c), both the air supply valve 235 and the exhaust valve 236 of the storage 234 are closed. As a result, the atmosphere in the processing container is exhausted from the first exhaust pipe 231.

In the processing of (d), both the air supply valve 235 and the exhaust valve 236 of the storage 234 are closed. The second processing gas is, for example, a source gas.

In FIG. 5E, both the air supply valve 235 and the exhaust valve 236 of the storage 234 are closed, and the atmosphere in the processing container is exhausted by the first exhaust pipe 231. In FIG. 5F, the processing of (a) is performed while the atmosphere in the storage 234 is exhausted to the vacuum exhaust apparatus (vacuum pump 246). After the exhaust of the inside of the storage 234, the processing returns to the processing of (b) (FIG. 5B), and the processing of (b), (c), (d), (f), and (g) may be repeated.

In (e), the processing of (a), (b), (c), (d), and (f) (FIGS. 5A to 5E) may be performed, and the processing of (a), (b), (c), (d), (f), and (g) (FIGS. 5A to 5F) may be performed. In (e), the processing of (a) to (d) (FIGS. 5A to 5D) may be performed a predetermined number of times. That is, these pieces of processing may be cyclically performed.

In (g), the degree of opening of the exhaust valve 236 may be controlled so that the exhaust amount from the storage 234 to the vacuum exhaust apparatus (vacuum pump 246) is a predetermined exhaust amount.

The processing of (g) may be performed before (a), or may be performed in parallel with (a). A case where (g) is performed in parallel with (a) includes: a case where (g) starts at the same time as (a), and (a) ends earlier than (g); a case where (g) starts after the start of (a), and (g) ends before the end of (a); and a case where (g) starts at the same time as (a) and (g) ends at the same time as (a).

In (g), the inside of the storage 234 may be exhausted to a reduced pressure atmosphere.

In the above description, an example has been described in which (a) is performed first, but the present disclosure is not limited thereto, and the source gas may be supplied first as illustrated in FIG. 4. That is, (d) is performed first.

Each piece of “processing” may be read as a “step”.

The first processing gas is a gas that reacts with the second processing gas. In a case where the second processing gas is a source gas, the first processing gas is, for example, a reducing gas. The reducing gas is a gas containing a hydrogen element, and it is possible to use at least one or more of, for example, H₂ gas, D₂ gas, monosilane (SiH₄) gas, disilane (Si₂H₆) gas, trisilane (Si₃H₈) gas, monogermane (GeH₄)—based gas, phosphine (PH₃) gas, and the like. In addition, it is possible to use a gas obtained by activating at least one or more of these. The H₂ gas and the D₂ gas are gases composed of hydrogen alone.

In addition, as an example, a case has been described where a gas containing the Mo element is used as a source gas (metal element-containing gas), but the present disclosure is not limited thereto. For example, there is a case where the present disclosure can be applied to processing using a gas containing at least one or more elements of ruthenium (Ru) element and tungsten (W) element as the source gas. These sources are exhausted from the processing container, then fixed, liquefied, and collected.

### (5) Effect of Reactant Gas Exhaust Step

According to this step, in (b), since the atmosphere in the processing container is exhausted to the first exhaust pipe 231 and the storage 234 of the second exhaust pipe 232, the discharge time of the first processing gas from the exhaust system can be shortened, and processing throughput can be improved. In (e), by performing (a) to (d) a predetermined number of times, it is possible to improve throughput of film-forming processing on the wafer 200.

In (f), by exhausting the atmosphere in the processing container by the first exhaust pipe 231 in a state where the exhaust of the atmosphere in the processing container by the storage 234 is stopped, it is possible to suppress the first processing gas and the second processing gas from being mixed together in the exhaust system.

(g) By exhausting the atmosphere in the storage 234 to the vacuum exhaust apparatus (vacuum pump 246) in a state where the exhaust of the atmosphere in the processing container by the first exhaust pipe 231 is stopped and the exhaust valve 236 is opened, it is possible to exhaust the atmosphere in the storage 234 in a short time.

In (g), by controlling the degree of opening of the exhaust valve 236 so that the exhaust amount from the storage 234 to the vacuum exhaust apparatus (vacuum pump 246) is a predetermined exhaust amount, it is possible to reduce loads of the vacuum pump 246 and the detoxifier 247. In addition, even when the pressure in the storage 234 rapidly decreases and a temperature in the storage 234 decreases, liquefaction of the gas in the storage 234 can be suppressed by control of a flow rate of the exhaust of the inside of the storage 234 by the exhaust valve 236 as described above.

When (g) is performed before (a), the inside of the storage 234 is exhausted before the supply of the high-pressure H₂ gas, for example. In this case, the pressure in the processing container can be regulated in (a). On the other hand, when (g) is performed in parallel with (a), the processing throughput is further improved.

In (g), when the inside of the storage 234 is exhausted to a reduced pressure atmosphere, a pressure difference between the processing container and the storage 234 increases. As a result, it is possible to increase the exhaust amount from the processing container to the storage 234 in (b) next.

### (6) Program

A program according to the present embodiment is a program that causes a computer to control the substrate processing apparatus 10 described above, the program causing, by the computer, the substrate processing apparatus 10 to execute:
(a) a procedure of supplying the first processing gas into the processing container (process chamber 201) in a state where the exhaust of the atmosphere in the processing container is stopped (FIG. 5A);
(b) a procedure of exhausting the atmosphere in the processing container to the first exhaust pipe 231 and the storage 234 of the second exhaust pipe 232 in a state where the exhaust valve 236 is closed and the air supply valve 235 is opened, after (a) (FIG. 5B);
(c) a procedure of exhausting the atmosphere in the processing container by the first exhaust pipe 231 in a state where the air supply valve 235 is closed to stop the exhaust of the atmosphere in the processing container by the storage 234, after (b) (FIG. 5C);
(d) a procedure of supplying the second processing gas into the processing container in a state where the air supply valve 235 is closed to stop the exhaust of the atmosphere in the processing container by the storage 234, after (c) (FIG. 5D); and
(e) a procedure of performing (a) to (d) to process the substrate (wafer 200) in the processing container.

Further, the following procedures (f) and (g) may be performed.
(f) A procedure of exhausting the atmosphere in the processing container by the first exhaust pipe 231 in a state where the air supply valve 235 and the exhaust valve 236 are closed to stop the exhaust of the atmosphere in the processing container by the storage 234, after (d) (FIG. 5E)
(g) A procedure of exhausting the atmosphere in the storage 234 to the vacuum exhaust apparatus (vacuum pump 246) in a state where the exhaust of the atmosphere in the processing container by the first exhaust pipe 231 is stopped and the exhaust valve 236 is opened (FIG. 5F)

In (e), the procedures (a), (b), (c), (d), and (f) (FIGS. 5A to 5E) may be executed, and the procedures (a), (b), (c), (d), (f), and (g) (FIGS. 5A to 5F) may be executed. In (e), the procedures (a) to (d) (FIGS. 5A to 5D) may be executed a predetermined number of times.

In (g), the degree of opening of the exhaust valve 236 may be controlled so that the exhaust amount from the storage 234 to the vacuum exhaust apparatus (vacuum pump 246) is a predetermined exhaust amount.

The procedure (g) may be executed before (a), or may be executed in parallel with (a).

In (g), the inside of the storage 234 may be exhausted to a reduced pressure atmosphere.

The program may be a program recorded in a computer-readable recording medium. In addition, the program may be provided as a computer-readable recording medium on which the program is recorded.

In the embodiment described above, as an example, a case has been described where the MoO₂Cl₂ gas is used as the metal-containing gas (Mo—containing gas), but the present disclosure is not limited thereto.

In the embodiment described above, as an example, a case has been described where the same kind of gas is used as the reducing gas used in the first step and the reducing gas used in the fifth step, but the present disclosure is not limited thereto. The reducing gas used in the first step and the reducing gas used in the fifth step may be gases having different molecular structures. For example, the H₂ gas may be used in the first step, and the D₂ gas or activated H₂ gas may be used in the fifth step. In the fifth step, at least one or more may be used of the PH₃ gas, and a silane—based gas and a borane—based gas described later. As the reducing gas used in the first step, a gas may be used having at least one or more of a characteristic of suppressing decomposition of the material containing the group 15 element and a characteristic of being a carrier of the material containing the group 15 element. As the reducing gas used in the fifth step, a gas may be used having at least one or more of a characteristic of reducing the Mo—containing gas serving as the source gas and a characteristic of suppressing decomposition of the first layer.

In the embodiment described above, as an example, a case has been described of using the gas containing P and H as the gas containing the group 15 element, but the present disclosure is not limited thereto, and it is possible to use other reducing gases, for example, silane—based gases such as monosilane (SiH₄) gas, disilane (Si₂H₆) gas, trisilane (Si₃H₈) gas, and tetrasilane (Si₄H₁₀), and borane-based gases such as monoborane (BH₃) and diborane (B₂H₆). However, with these gases, it is difficult to obtain a by-product that is easily desorbed, such as POCl₄ generated in a case where PH₃ is used, so that characteristics of the Mo—containing film may be deteriorated. Thus, the gas containing the group 15 element is preferably a gas containing P. More preferably, a gas containing P and H is preferable.

In the embodiment described above, as an example, a case has been described where the gas containing the Mo element is used as the source gas (metal element-containing gas), but the present disclosure is not limited thereto. For example, there is a case where the present disclosure can be applied to processing using a gas containing at least one or more elements of ruthenium (Ru) element and tungsten (W) element as the source gas.

In the embodiment described above, an example has been described in which a film is formed by use of the substrate processing apparatus that is a batch-type vertical apparatus that processes a plurality of substrates at a time; however, the present disclosure is not limited thereto, and is suitably applicable to a case where a film is formed by use of a substrate processing apparatus of a single wafer type that processes one or several substrates at a time. In the above-described embodiments, an example has been described in which a film is formed by use of a substrate processing apparatus including a hot wall type processing furnace. The present disclosure is not limited to the above-described embodiments, and is suitably applicable to a case where a film is formed by use of a substrate processing apparatus including a cold wall type processing furnace. Even in a case where these substrate processing apparatuses are used, a film can be formed with a sequence and a processing condition similar to those in the embodiment described above.

It is preferable to individually prepare (prepare a plurality of) process recipes (programs in which processing procedure, a processing condition, and the like, are described) to be used for forming these various thin films according to the content of substrate processing (film type, composition ratio, film quality, film thickness, processing procedure, processing condition, and the like, of a thin film to be formed). Then, when substrate processing is started, it is preferable to appropriately select an appropriate process recipe from among a plurality of process recipes according to the content of the substrate processing.

Specifically, it is preferable to store (install) a plurality of process recipes individually prepared according to the contents of the substrate processing in advance in the memory 121c included in the substrate processing apparatus via a telecommunication line or a recording medium (external memory 123) in which the process recipes are recorded. Then, when the substrate processing is started, the CPU 121a included in the substrate processing apparatus preferably appropriately selects an appropriate process recipe from among the plurality of process recipes stored in the memory 121c according to the content of the substrate processing. With such a configuration, one substrate processing apparatus can generally form thin films of various film types, composition ratios, film qualities, and film thicknesses with good reproducibility. In addition, it is possible to reduce an operational burden (for example, a burden of inputting a processing procedure, a processing condition, and the like) on an operator, and it is possible to quickly start the substrate processing while avoiding an operation error.

In addition, the present disclosure can also be implemented, for example, by changing a process recipe of an existing substrate processing apparatus. In a case where the process recipe is changed, a process recipe according to the present disclosure can be installed in the existing substrate processing apparatus via a telecommunication line or a recording medium in which the process recipe according to the present disclosure is recorded, or a process recipe itself of the existing substrate processing apparatus can be changed to the process recipe according to the present disclosure by operation of an input/output device of the existing substrate processing apparatus.

The above-described embodiments can be used in combination as appropriate. Processing procedures and processing conditions at this time can be similar to the processing procedures and the processing conditions in the above-described embodiments, for example.

The embodiments of the present disclosure have been specifically described above. However, the present disclosure is not limited to the embodiments described above, and thus can be variously modified without departing from the gist of the present disclosure.

According to an embodiment of the present disclosure, it is possible to shorten the discharge time of the gas from the exhaust system and improve the processing throughput.

What is claimed is:

1. A method of processing a substrate, using a substrate processing apparatus including: a processing container in which the substrate is processed; a first exhaust pipe connected to the processing container and an exhaust apparatus that exhausts an atmosphere in the processing container; a second exhaust pipe connected to the exhaust apparatus and the processing container in parallel with the first exhaust pipe; a storage provided in the second exhaust pipe; an air supply valve provided on an air supply side of the storage in the second exhaust pipe; and an exhaust valve provided on an exhaust side of the storage in the second exhaust pipe,
the method comprising:
(a) supplying a first processing gas into the processing container in a state where exhaust of the atmosphere in the processing container is stopped;
(b) exhausting the atmosphere in the processing container to the first exhaust pipe and the storage of the second exhaust pipe in a state where the exhaust valve is closed and the air supply valve is opened, after (a);
(c) exhausting the atmosphere in the processing container by the first exhaust pipe in a state where the air supply valve is closed to stop the exhaust of the atmosphere in the processing container by the storage, after (b);
(d) supplying a second processing gas into the processing container in a state where the air supply valve is closed to stop the exhaust of the atmosphere in the processing container by the storage, after (c); and
(e) performing (a) to (d) to process the substrate in the processing container.

2. The method of claim 1, comprising
(f) exhausting the atmosphere in the processing container by the first exhaust pipe in a state where the air supply valve and the exhaust valve are closed to stop the exhaust of the atmosphere in the processing container by the storage, after (d), wherein
(a), (b), (c), (d), and (f) are performed in (e).

3. The method of claim 2, comprising
(g) exhausting the atmosphere in the storage by the exhaust apparatus in a state where the exhaust of the atmosphere in the processing container by the first exhaust pipe is stopped and the exhaust valve is opened, after (f),
wherein
(a), (b), (c), (d), (f), and (g) are performed in (e).

4. The method of claim 3, wherein
a degree of opening of the exhaust valve is controlled to cause an exhaust amount from the storage to the exhaust apparatus to be a predetermined exhaust amount, in (g).

5. The method of claim 3, wherein
(g) is performed before (a).

6. The method of claim 4, wherein
(g) is performed before (a).

7. The method of claim 3, wherein
(g) is performed in parallel with (a).

8. The method of claim 4, wherein
(g) is performed in parallel with (a).

9. The method of claim 1, wherein
(a) to (d) are performed a predetermined number of times in (e).

10. The method of claim 3, wherein
exhaust is performed until an inside of the storage is brought into a reduced pressure atmosphere in (g).

11. The method of claim 4, wherein
exhaust is performed until an inside of the storage is brought into a reduced pressure atmosphere in (g).

12. A method of manufacturing a semiconductor device, comprising the method of claim 1.

13. A non-transitory computer-readable recording medium recording a program that causes a computer to control a substrate processing apparatus including: a processing container in which a substrate is processed; a first exhaust pipe connected to the processing container and an exhaust apparatus that exhausts an atmosphere in the processing container; a second exhaust pipe connected to the exhaust apparatus and the processing container in parallel with the first exhaust pipe; a storage provided in the second exhaust pipe; an air supply valve provided on an air supply side of the storage in the second exhaust pipe; and an exhaust valve provided on an exhaust side of the storage in the second exhaust pipe,
the program causing, by the computer, the substrate processing apparatus to execute:
(a) a procedure of supplying a first processing gas into the processing container in a state where exhaust of the atmosphere in the processing container is stopped;
(b) a procedure of exhausting the atmosphere in the processing container to the first exhaust pipe and the storage of the second exhaust pipe in a state where the exhaust valve is closed and the air supply valve is opened, after (a);
(c) a procedure of exhausting the atmosphere in the processing container by the first exhaust pipe in a state where the air supply valve is closed to stop the exhaust of the atmosphere in the processing container by the storage, after (b);
(d) a procedure of supplying a second processing gas into the processing container in a state where the air supply valve is closed to stop the exhaust of the atmosphere in the processing container by the storage, after (c); and
(e) a procedure of performing (a) to (d) to process the substrate in the processing container.

14. A substrate processing apparatus comprising:
a processing container in which a substrate is processed;
a first exhaust pipe connected to the processing container and an exhaust apparatus that exhausts an atmosphere in the processing container;
a second exhaust pipe connected to the exhaust apparatus and the processing container in parallel with the first exhaust pipe; a storage provided in the second exhaust pipe;
an air supply valve provided on an air supply side of the storage in the second exhaust pipe;
an exhaust valve provided on an exhaust side of the storage in the second exhaust pipe;
a gas supplier capable of supplying a first processing gas and a second processing gas to the processing container; and
a controller configured to be capable of controlling the first exhaust pipe, the second exhaust pipe, and the gas supplier to perform:
(a) processing of supplying a first processing gas into the processing container in a state where exhaust of the atmosphere in the processing container is stopped;
(b) processing of exhausting the atmosphere in the processing container to the first exhaust pipe and the storage of the second exhaust pipe in a state where the exhaust valve is closed and the air supply valve is opened, after (a);
(c) processing of exhausting the atmosphere in the processing container by the first exhaust pipe in a state where the air supply valve is closed to stop the exhaust of the atmosphere in the processing container by the storage, after (b);
(d) processing of supplying a second processing gas into the processing container in a state where the air supply valve is closed to stop the exhaust of the atmosphere in the processing container by the storage, after (c); and
(e) processing of performing (a) to (d) to process the substrate in the processing container.
